(19) United States
(12) Patent Application Publication
(10) Pub. No.: US 2011/0180310 A1
(43) Pub. Date: Jul. 28, 2011

(54) PRINTED CIRCUIT BOARD

(75) Inventor: CHANG-TE LIAO, Tu-Cheng (TW)

(73) Assignee: HON HAI PRECISION INDUSTRY CO., LTD., Tu-Cheng (TW)

(21) Appl. No.: 12/770,741

(22) Filed: Apr. 30, 2010

(30) Foreign Application Priority Data
Jan. 28, 2010 (CN) 201020301811.2

(51) Int. Cl. H05K 1/09; H05K 1/11

(52) U.S. Cl. 174/257; 174/262; 174/264

(57) ABSTRACT

A printed circuit board includes a substrate including through holes, pad portions arranged on surfaces of the substrate, and insulating areas. Each of the pad portions includes a first pad surrounding a corresponding through hole and a second pad. Each of the insulating areas is between each of the first pads and each of the second pads to electrically insulate each of the first pads and each of the second pads from each other. Attachment or removal of conductive layers to or from the insulating areas allows electrical connection or disconnection between the first pads and the second pads.

### BACKGROUND

1. Technical Field

The present disclosure relates to a printed circuit board.

2. Description of Related Art

A typical electrical device generally includes a printed circuit board (PCB) on which a plurality of components, such as resistors, capacitors, and/or Dual In-line Package (DIP) components, etc., are mounted. The components are electrically connected to signal layers, such as solid copper layers, of the PCB. Frequently, the PCB includes a connector to electrically connect or disconnect the signal layers to or from each other in order to test whether various functions of the components meet standard requirements. However, production cost of the PCB is increased by the requirement for the connector, and efforts toward minimizing device profile are compromised.

Therefore, a need exists in the industry to overcome the described limitations.

### BRIEF DESCRIPTION OF THE DRAWINGS

FIG. 1 is a cross-sectional view of a first embodiment of a printed circuit board (PCB) of the disclosure.

FIG. 2 is a plan view of FIG. 1.

FIG. 3 is a cross-sectional view of a plurality of conductive layers attached to surfaces of the PCB of FIG. 1.

FIG. 4 is a cross-sectional view of a second embodiment of a PCB.

FIG. 5 is a plan view of FIG. 4.

FIG. 6 is a cross-sectional view of a plurality of conductive layers attached to surfaces of the PCB of FIG. 4.

### DETAILED DESCRIPTION

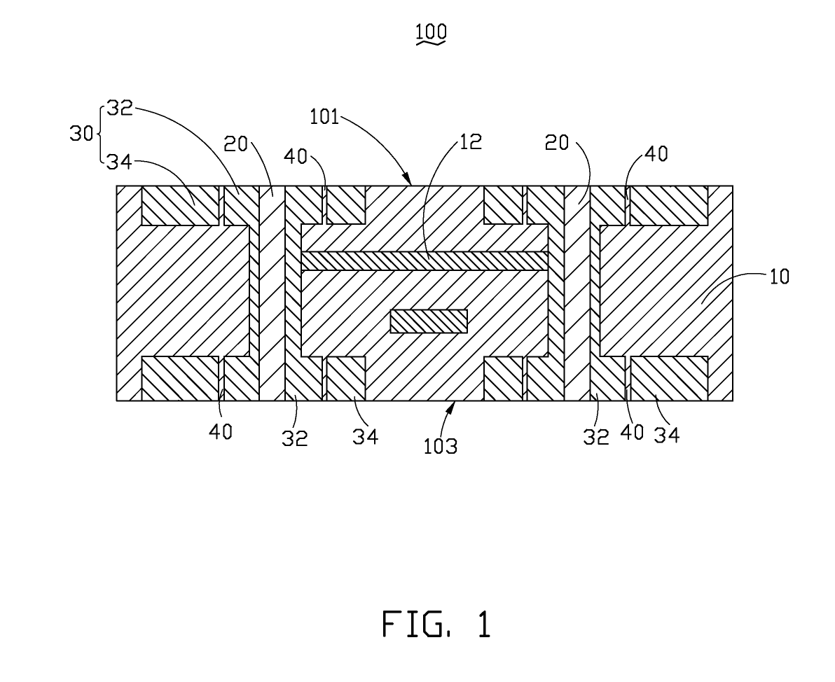

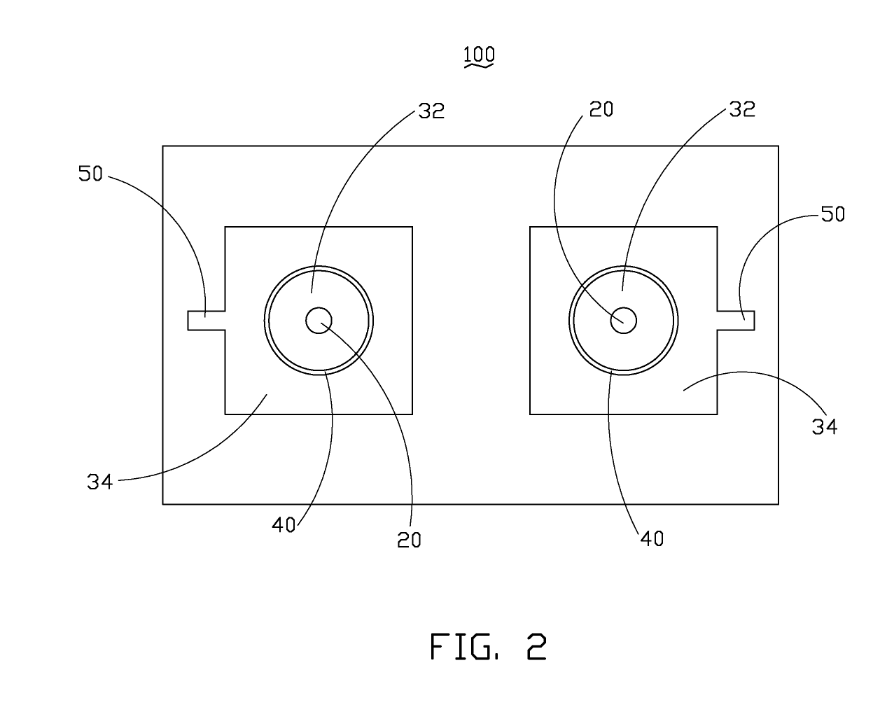

Referring to FIG. 1 and FIG. 2, a printed circuit board (PCB) 100 of a first embodiment of the present disclosure is illustrated. The PCB 100 includes a substrate 10 including a plurality of through holes 20, a plurality of pad portions 30, and a plurality of insulating areas 40.

The substrate 10 includes a first surface 101, a second surface 103 opposite to the first surface 101, and a plurality of metal layers 12 embedded in the substrate 10 to electrically connect the through holes 20 to each other where needed.

In one embodiment, the conductive layers 12 may be arranged in a straight line, an L-shaped line, a Z-shaped line, a C-shaped line, or an S-shaped line.

The through holes 20 extend through the substrate 10. In the illustrated embodiment, the through holes 20 may be vias or mounting holes. The through holes 20 are filled with solder masks to prevent solder from overflowing into the through holes 20 when the PCB 100 goes through a wave soldering procedure.

In the illustrated embodiment, the pad portions 30 are arranged on the first and second surfaces 101, 103 of the substrate 10. Each of the pad portions 30 includes a substantially circular first pad 32 surrounding a corresponding through hole 20, and a second pad 34. The second pad 34 may be circular or square. In the illustrated embodiment, the first pads 32 and the second pads 34 are copper foils.

Alternatively, the pad portions 30 are arranged on the first surface 101 or the second surface 103 of the substrate 10.

Each of the insulating areas 40 is between each of the first pads 32 and each of the second pads 34 to electrically insulate each of the first pads 32 and each of the second pads 34 from each other. In the illustrated embodiment, each of the insulating areas 40 is an etched hollow area between each of the first pads 32 and each of the second pads 34. Alternatively, each of the etched hollow areas may be filled with an insulation material.

In the illustrated embodiment, the PCB 100 further includes a plurality of signal layers 50 electrically connected to the second pads 34. The first pads 32 electrically connect the through holes 20 to the metal layers 12. In the illustrated embodiment, the signal layers 50 and the metal layers 12 are copper foils.

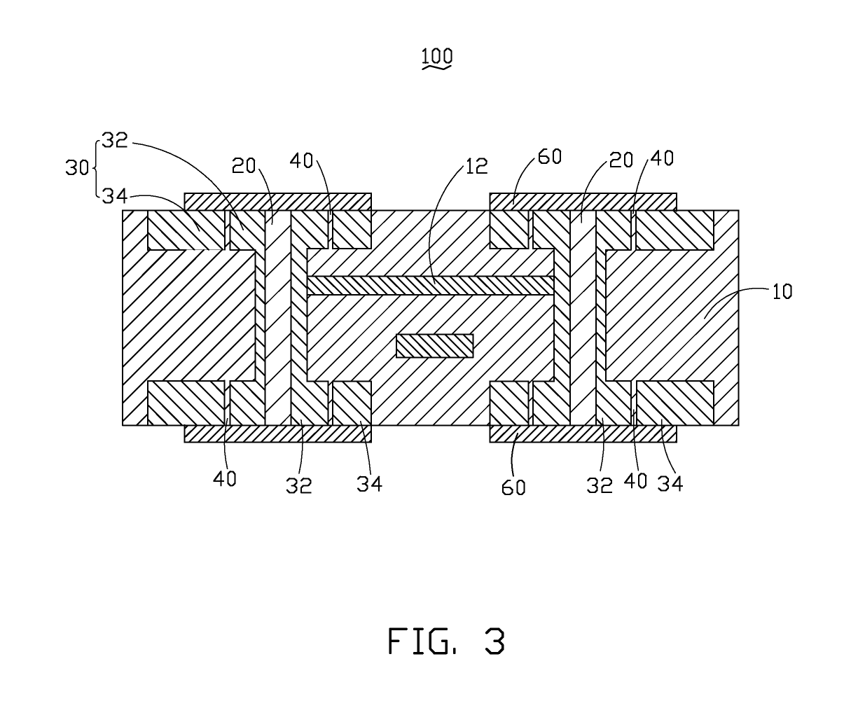

Referring to FIG. 3, in use, if the signal layers 50 need to be electrically connected, conductive layers 60 are attached to surfaces of the insulating areas 40 to electrically connect the first pads 32 and the second pads 34 to each other. If the signal layers 50 do not need to be connected, the conductive layers 60 attached to surfaces of the insulating areas 40 are removed. That is, attachment or removal of the conductive layers 60 to or from the insulating areas 40 allows electrical connection or disconnection of the first pads 32 and the second pads 34 to or from each other.

In the illustrated embodiment, the conductive layers 60 are solder tin layers, thus attachment or removal of the conductive layers 60 to or from the insulating areas 40 is easy.

Because attachment or removal of the conductive layers 60 to or from the insulating areas 40 allows electrical connection or disconnection between the first pads 32 and the second pads 34, the PCB 100 requires no additional structure or elements to electrically connect or disconnect the first pads 32 and the second pads 34 to or from each other, with the desired simplification of circuit design and reduction of production cost of the PCB 100 being achieved.

With the through holes 20 electrically connected by the metal layers 12 embedded in the substrate 10, a distance between the two adjacent through holes 20 is not limited and can be adjusted to suit.

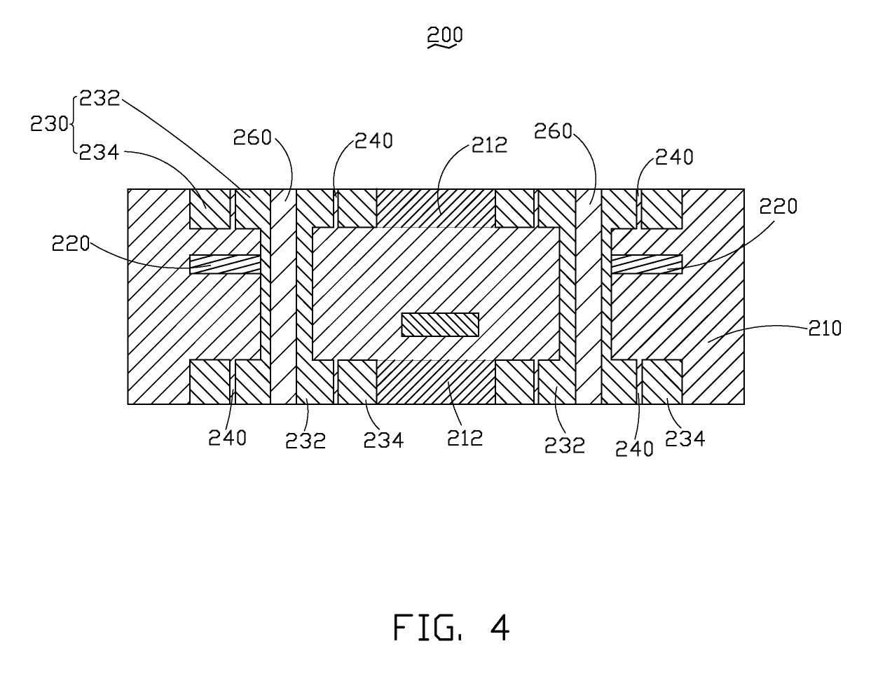

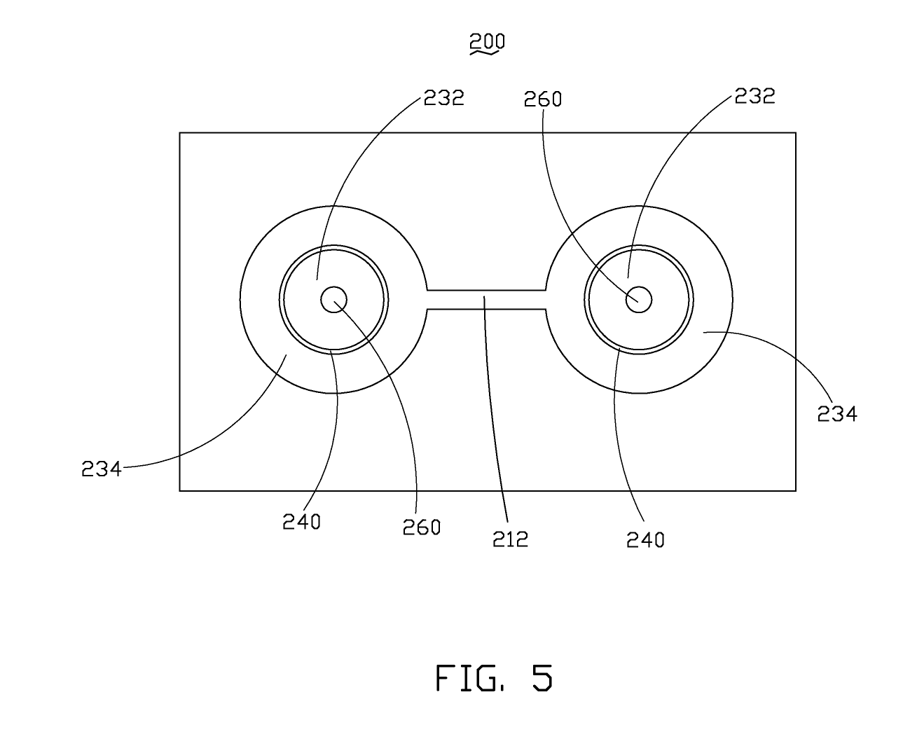

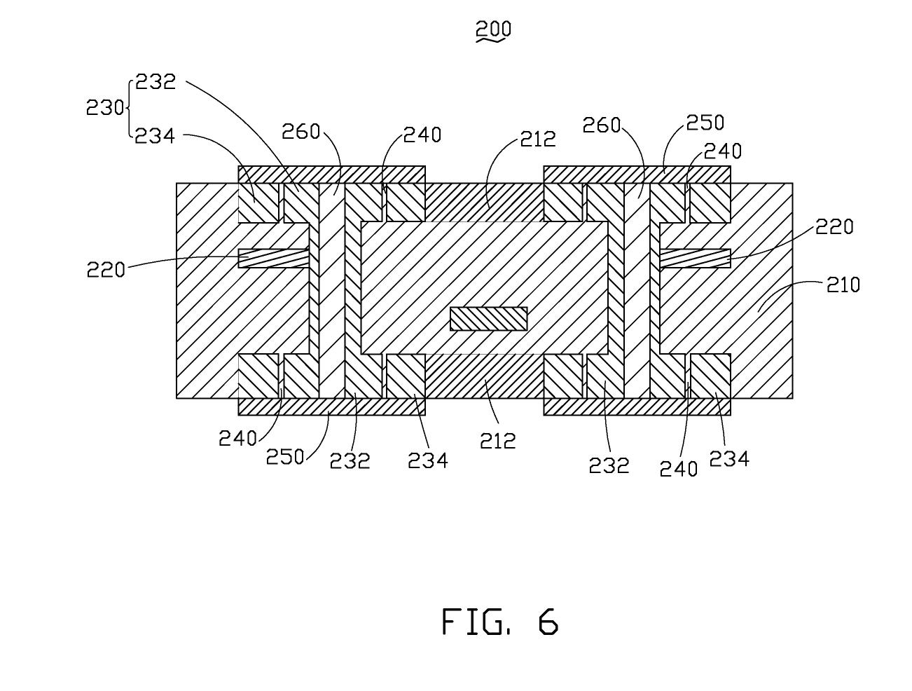

Referring to FIGS. 4, 5, and 6, a PCB 200 of a second embodiment of the present disclosure is illustrated. The PCB 200 includes a substrate 210 including a plurality of through holes 260, a plurality of pad portions 230 including a first pad 232 and a second pad 234, and a plurality of insulating areas 240.

The substrate 210 differs from the substrate 10 shown in FIG. 1 in that the substrate 210 includes a plurality of metal layers 212 arranged on surfaces of the substrate 210 and electrically connected to the second pads 234, and a plurality of signal layers 220 embedded in the substrate 210 and electrically connected to the first pads 232.

The through holes 260 are electrically connected to the metal layers 212 arranged on surfaces of the substrate 210, thus a distance between two adjacent through holes 260 is relatively short.

In use, if the signal layers 220 need to be electrically connected, conductive layers 250 are attached to surfaces of the insulating areas 240 to electrically connect the first pads 232 to the second pads 234. If the signal layers 220 do not need to be electrically connected, the conductive layers 250 attached to surfaces of the insulating areas 240 are removed.

The PCB 200 can substantially perform the same function as the PCB 100 described above.

Alternatively, the PCB 100 and the PCB 200 may be different areas of a same PCB.

While embodiments of the present disclosure have been described above, it should be understood that they have been presented by way of example only and not by way of limitation. Thus the breadth and scope of the present disclosure should not be limited by the above-described embodiments, but should be defined only in accordance with the following claims and their equivalents.

What is claimed is:

1. A printed circuit board, comprising:
a substrate comprising a plurality of through holes extending through the substrate;
a plurality of pad portions arranged on at least one surface of the substrate, each of the pad portions comprising a first pad surrounding a corresponding through hole and a second pad; and
a plurality of insulating areas each between each of the first pads and each of the second pads to electrically insulate each of the first pads and each of the second pads from each other;
wherein attachment or removal of conductive layers to or from the insulating areas allows electrical connection or disconnection of the first pads and the second pads to or from each other.

2. The printed circuit board as recited in claim 1, wherein the conductive layers are solder tin layers.

3. The printed circuit board as recited in claim 1, wherein the through holes are filled with solder masks to prevent solder from overflowing into the through holes when the PCB goes through a wave soldering procedure.

4. The printed circuit board as recited in claim 1, wherein each of the first pads is substantially circular.

5. The printed circuit board as recited in claim 4, wherein each of the second pads is substantially circular or square.

6. The printed circuit board as recited in claim 1, wherein each of the plurality of insulating areas is an etched hollow area between each of the first pads and each of the second pads.

7. The printed circuit board as recited in claim 6, wherein each of the etched hollow areas is filled with an insulation material.
